(19) United States
(12) Patent Application Publication
(10) Pub. No.: US 2026/0107792 A1
(43) Pub. Date: Apr. 16, 2026

(54) SEMICONDUCTOR MODULE

(71) Applicant: FUJI ELECTRIC CO., LTD., Kanagawa (JP)

(72) Inventor: Ryoga KIGUCHI, Hino-city (JP)

(21) Appl. No.: 19/245,365

(22) Filed: Jun. 22, 2025

(30) Foreign Application Priority Data
Jul. 31, 2024 (JP) 2024-124821

(51) Int. Cl. H10W 70/60; H10W 40/50; H10W 70/652; H10W 70/654; H10W 90/10

(52) U.S. Cl. CPC H10W 70/611; H10W 40/50; H10W 70/652; H10W 70/654; H10W 90/10

(57) ABSTRACT

Provided is a semiconductor module including a stacked substrate in which a plurality of wiring layers are stacked, and a plurality of semiconductor devices mounted on a first surface of the stacked substrate, wherein the plurality of wiring layers have a first wiring layer having a high-potential wiring to which a high potential is applied, a second wiring layer having a low-potential wiring to which a low potential is applied, and a third wiring layer having a connection wiring which connects the plurality of semiconductor devices mounted on the first surface of the stacked substrate to each other, and the high-potential wiring and the low-potential wiring are at least partially overlapped with each other in a stack direction.

The contents of the following patent application(s) are incorporated herein by reference:
NO. 2024-124821 filed in JP on Jul. 31, 2024.

### BACKGROUND

### 1. Technical Field

The present invention relates to a semiconductor module.

### 2. Related Art

Paragraph 99 of Patent Document 1 describes “Mirroring a first pattern and a second pattern regarding patterns connecting a power conversion circuit and a control circuit is more restricted in arrangement of the patterns, compared to when both patterns are mirrored within the power conversion circuit and the control circuit. Therefore, by adopting SMDs or surface mounted devices with mirrored pin arrangements on a substrate 30 having both patterns as in the present embodiment, the aforementioned effect of making it possible to more easily mirror both patterns is significantly exhibited.”

### PRIOR ART DOCUMENTS

### Patent Document

Patent Document 1: Japanese Patent Application Publication No. 2020-188656

### BRIEF DESCRIPTION OF THE DRAWINGS

FIG. 1 is a perspective view of a switching element 10 according to the present embodiment.

FIG. 2 is a perspective view of a semiconductor device 200 according to the present embodiment.

FIG. 3 is a perspective view of a semiconductor module 300 according to the present embodiment.

FIG. 4 is a schematic view illustrating an internal structure of the semiconductor module 300 according to the present embodiment.

FIG. 5 illustrates a connection of each wiring within the semiconductor module 300 according to the present embodiment.

FIG. 6 is a schematic cross-sectional view illustrating the semiconductor module 300 according to the present embodiment.

FIG. 7 is a schematic top view illustrating a second surface of a stacked substrate 310 of the semiconductor module 300.

FIG. 8 is a schematic view of a first level wiring layer 500 of the stacked substrate 310 of the semiconductor module 300.

FIG. 9 is a schematic view of a second level wiring layer 510 of the stacked substrate 310 of the semiconductor module 300.

FIG. 10 is a schematic view of a third level wiring layer 520 of the stacked substrate 310 of the semiconductor module 300.

FIG. 11 is a schematic view of a fourth level wiring layer 530 of the stacked substrate 310 of the semiconductor module 300.

FIG. 12 is a schematic view of a fifth level wiring layer 540 of the stacked substrate 310 of the semiconductor module 300.

FIG. 13 illustrates another example of a connection of each wiring within the semiconductor module 300 according to the present embodiment.

FIG. 14 illustrates a configuration example of a control device 320 of the semiconductor module 300.

### DESCRIPTION OF EXEMPLARY EMBODIMENTS

Hereinafter, embodiments of the present invention will be described. However, the following embodiments are not for limiting the invention according to the claims. In addition, not all of the combinations of features described in the embodiments are essential to the solving means of the invention.

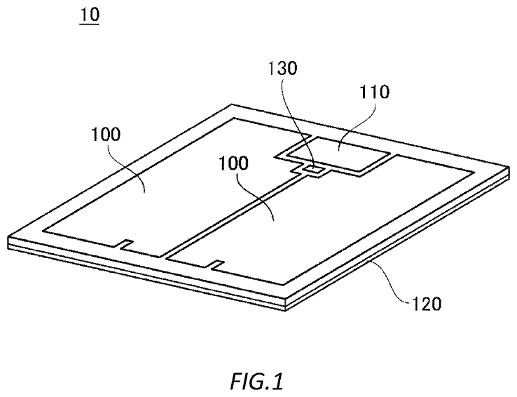

FIG. 1 is a perspective view of a switching element 10 according to the present embodiment. The switching element 10 is a semiconductor switching element such as a MOSFET or Metal-Oxide-Semiconductor Field-Effect Transistor. The switching element 10 may be a power MOSFET having a vertical structure. The switching element 10 may be a SiC semiconductor element such as a SiC-MOSFET capable of faster switching, or may be one in which a wide-gap semiconductor such as GaN, diamond, gallium nitride material, gallium oxide material, AlN, AlGaN, or ZnO is used. Instead of the above, the switching element 10 may be a semiconductor switching element such as an IGBT or Insulated Gate Bipolar Transistor or may be a SiC-IGBT. The switching element 10 may be a HEMT or High Electron Mobility Transistor.

The switching element 10 may be a semiconductor chip having a first main electrode 100 and a control electrode 110 on one surface, which is a surface on an upper side in the figure, and having a second main electrode 120 on an opposite surface. In the example of the present figure, the switching element 10 further has a sense electrode 130 on the surface on the upper side in the figure. When the switching element 10 is a MOSFET, the switching element 10 has a source and a drain as the first main electrode 100 and the second main electrode 120, has a gate as the control electrode 110, and has a sense source as the sense electrode 130. When the switching element 10 is an IGBT, the switching element 10 has an emitter and a collector as the first main electrode 100 and the second main electrode 120, has a gate as the control electrode 110, and has a sense emitter as the sense electrode 130. In the present embodiment, for convenience of description, the switching element 10 is illustrated as a MOSFET.

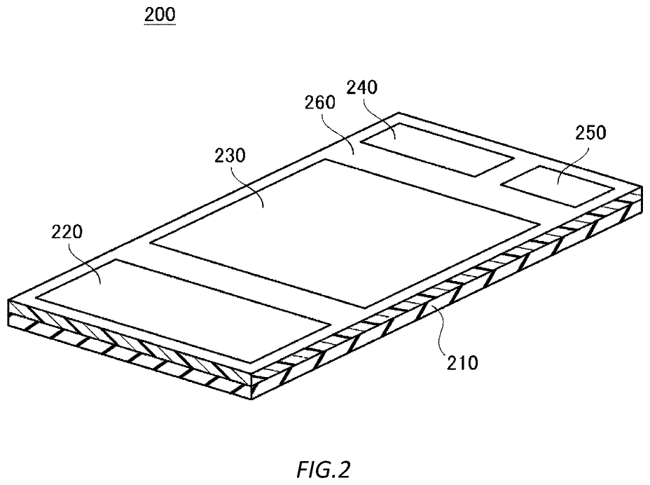

FIG. 2 is a perspective view of a semiconductor device 200 according to the present embodiment. In general, a semiconductor module using a switching element such as the switching element 10 illustrated in FIG. 1 has a structure in which one surface of the switching element, which is, for example, a surface on a side with the second main electrode 120, is bonded to a wiring pattern on a substrate, and each electrode on another surface, which is, for example, each of the first main electrode 100, the control electrode 110, and the sense electrode 130, is electrically connected to another wiring pattern by wire bonding. Such a semiconductor module is implemented as an integral module by encapsulating, using a resin, a substrate on which the switching element is mounted, each bonding wire, and each metal plate connected to a positive terminal, a negative terminal, and an output terminal.

In contrast, the semiconductor device 200 has a structure in which each electrode plate electrically connected to each electrode of the switching element 10 is exposed to one surface of the plate-shaped semiconductor device 200. In the present embodiment, the semiconductor device 200 includes a mounting substrate 210, a first main electrode plate 220, a second main electrode plate 230, a control electrode plate 240, a sub-electrode plate 250, and an encapsulating portion 260.

The switching element 10 is mounted on a mounting surface, which is a surface on an upper side in the figure, of the mounting substrate 210. The first main electrode plate 220 is provided on one surface, which is the mounting surface, of the mounting substrate 210, and is electrically connected to the first main electrode 100 of the switching element 10. The second main electrode plate 230 is provided on one surface, which is the mounting surface, of the mounting substrate 210, and is electrically connected to the second main electrode 120 of the switching element 10. The control electrode plate 240 is provided on one surface, which is the mounting surface, of the mounting substrate 210, and is electrically connected to the control electrode 110 of the switching element 10. The sub-electrode plate 250 is electrically connected to the first main electrode 100 of the switching element 10. Herein, the first main electrode plate 220, the second main electrode plate 230, the control electrode plate 240, and the sub-electrode plate 250 are exposed to a surface opposite to a side with the mounting substrate 210 of the semiconductor device 200, the surface being on a side with the mounting surface for the switching element 10 in the mounting substrate 210. The encapsulating portion 260 covers the mounting surface for the switching element 10 in the mounting substrate 210 while exposing the first main electrode plate 220, the second main electrode plate 230, the control electrode plate 240, and the sub-electrode plate 250.

Instead of modularizing the switching element such as the switching element 10 as previously described, by bonding each electrode plate on one surface of the semiconductor device 200 to a wiring pattern on the substrate by using the semiconductor device 200 of the present embodiment, all the electrodes necessary for the switching element 10 can be electrically connected to respective wirings on the substrate without wire bonding.

It is to be noted that the semiconductor device 200 may further have an electrode plate to be electrically connected to the sense electrode 130 on a same surface as, for example, the first main electrode plate 220. While both of the first main electrode plate 220 and the sub-electrode plate 250 are electrically connected to the first main electrode 100 of the switching element 10, the first main electrode plate 220 has a larger area and is used for a large current to flow therethrough and the sub-electrode plate 250 is used for controlling the switching element 10 in a pair with the control electrode plate 240. In another embodiment, the semiconductor device 200 may not include the sub-electrode plate 250, and in this case, the first main electrode plate 220 is also used for controlling the switching element 10.

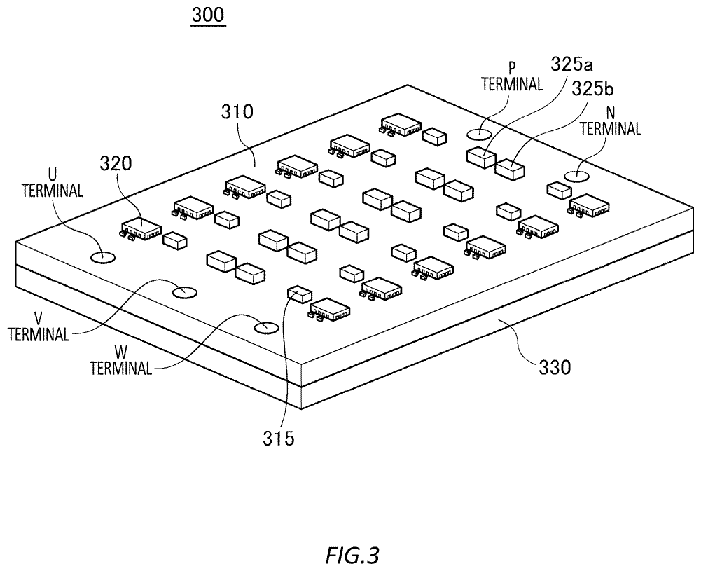

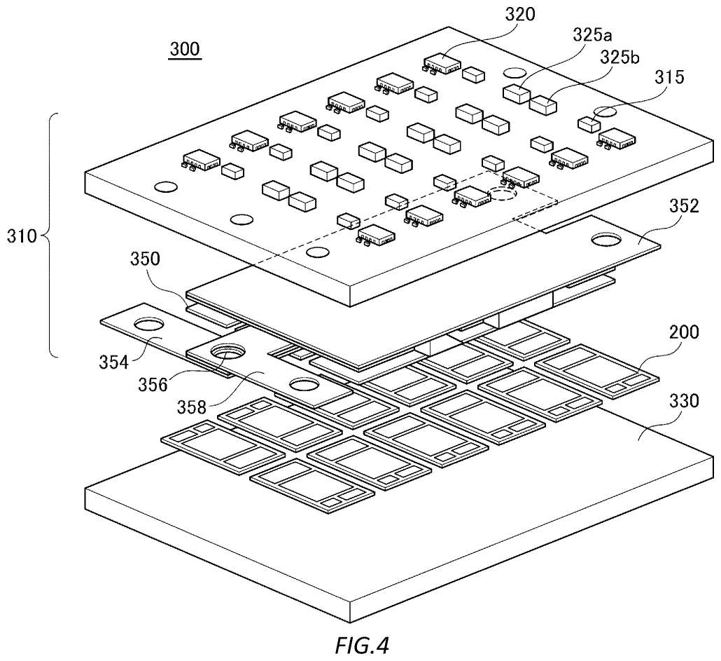

FIG. 3 is a perspective view of a semiconductor module 300 according to the present embodiment. FIG. 4 is a schematic view illustrating an internal structure of the semiconductor module 300 according to the present embodiment. The semiconductor module 300 according to the present embodiment is an inverter device. The semiconductor module 300 includes a plurality of semiconductor devices 200, a stacked substrate 310, a temperature sensor 315, at least one control device 320, at least one snubber capacitor 325, and a heat radiator 330.

The plurality of semiconductor devices 200 are each allocated to an upper arm and a lower arm of each phase among one or more phases. In the example in FIG. 3 and FIG. 4, the semiconductor module 300 is a three-phase inverter, and for each phase, two semiconductor devices 200 are allocated to the upper arm and two semiconductor devices 200 are allocated to the lower arm. Accordingly, the semiconductor module 300 includes twelve, which is calculated by three phases*(two for the upper arm and two for the lower arm), semiconductor devices 200. It is to be noted that the semiconductor module 300 may include any number of semiconductor devices 200 depending on the application.

The stacked substrate 310 may be a print wiring substrate, and its first surface is mounted with the plurality of semiconductor devices 200. Each electrode on the first surface of the stacked substrate 310 is connected to each of the first main electrode plate 220, the second main electrode plate 230, the control electrode plate 240, and the sub-electrode plate 250 of each semiconductor device 200. The stacked substrate 310 is a plurality of wiring layers which are stacked. The stacked substrate 310 has a P wiring 350, an N wiring 352, a U wiring 354, a V wiring 356, and a W wiring 358 within the plurality of wiring layers. It is to be noted that in FIG. 4, the P wiring 350, the N wiring 352, the U wiring 354, the V wiring 356, and the W wiring 358 are schematically illustrated separately on a lower side of the substrate of the stacked substrate 310 to make the structure of the wiring layers easier to see.

The P wiring 350, the N wiring 352, the U wiring 354, the V wiring 356, and the W wiring 358 may be conductive patterns formed in wiring layers different from each other in an inner layer of the stacked substrate 310. The stacked substrate 310 may be formed by bonding, with a resin or the like, and stacking a plurality of substrates on which the conductive pattern corresponding to each of the P wiring 350, the N wiring 352, the U wiring 354, the V wiring 356, and the W wiring 358 have been formed. In the present embodiment, the P wiring 350 may be a high-potential wiring to which a high potential is applied, and the N wiring 352 is a low-potential wiring to which a low potential is applied. Each of the U wiring 354, the V wiring 356, and the W wiring 358 may be an output wiring which connects the plurality of semiconductor devices 200 to an output terminal formed on a second surface of the stacked substrate 310.

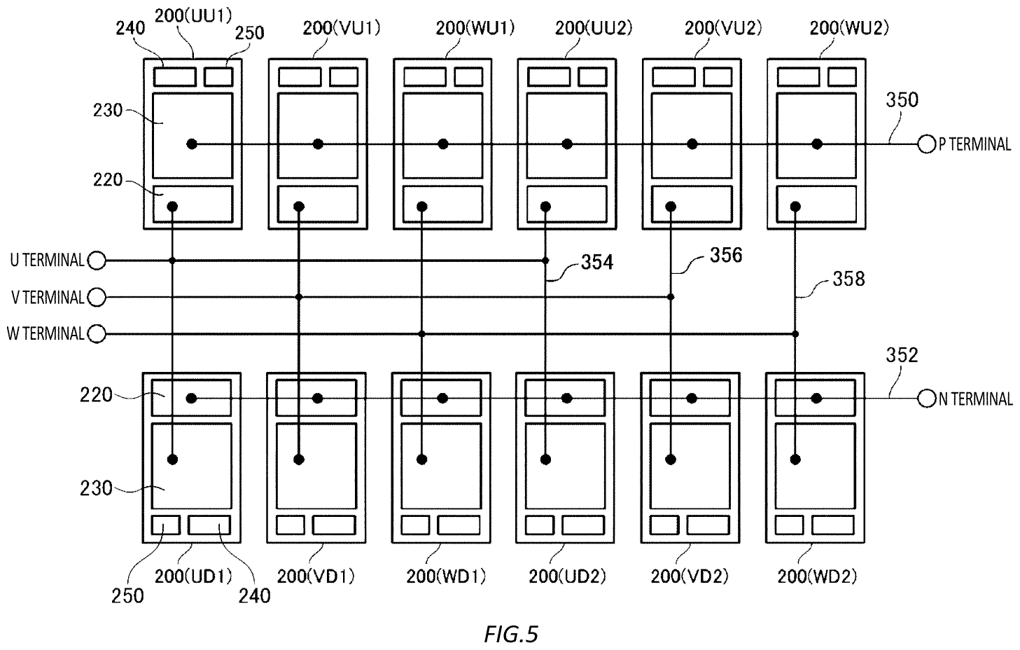

On the second surface on a side opposite to the first surface, the stacked substrate 310 has a terminal which connects to the first main electrode plate 220 of the plurality of semiconductor devices 200 via a wiring within the stacked substrate 310, and a terminal which connects to the second main electrode plate 230 via a wiring within the stacked substrate 310. In the present embodiment, the stacked substrate 310 has a P terminal (positive terminal), an N terminal (negative terminal), a U terminal (U-phase output terminal), a V terminal (V-phase output terminal), and a W terminal (W-phase output terminal) on the second surface. The P terminal and the N terminal may be arranged along one side of the second surface of the stacked substrate 310, and the U terminal, the V terminal, and the W terminal may be arranged along another side of the second surface of the stacked substrate 310. The connection between each terminal provided on the second surface of the stacked substrate 310 and the one or more semiconductor devices 200 by each wiring such as the P wiring 350 will be described below with reference to FIG. 5.

The at least one temperature sensor 315 may be arranged on a side with the second surface of the stacked substrate 310 and detect a temperature of at least one of the plurality of semiconductor devices 200. The one or more temperature sensors 315 may be, for example, a thermistor, a thermocouple, or the like. The plurality of temperature sensors 315 may each detect a temperature of the plurality of semiconductor devices 200. One of the plurality of temperature sensors 315 may detect the temperature of the plurality of semiconductor devices 200.

The at least one temperature sensor 315 may be arranged so as to be overlapped with at least one of the plurality of semiconductor devices 200 in a stack direction. For example, each temperature sensor 315 may be arranged on the second surface of the stacked substrate 310 at a position where a distance between the temperature sensor 315 and the semiconductor devices 200 to be detected is minimized. The temperature sensor 315 corresponding to the at least one semiconductor device 200 of the plurality of semiconductor devices 200 may be mounted at a position which overlaps with a conductor connected to the semiconductor device 200 to be detected in the stack direction. The plurality of temperature sensors 315 may be fixed on the second surface of the stacked substrate 310 in a same arrangement in which the semiconductor devices 200 are mounted on the first surface of the stacked substrate 310. In the present embodiment, the plurality of temperature sensors 315 may be fixed side by side in two rows, i.e. two rows*six is twelve, on the second surface of the stacked substrate 310. It is to be noted that each temperature sensor 315 may be at least partially embedded on the side with the second surface of the stacked substrate 310.

The at least one control device 320 is arranged on the second surface of the stacked substrate 310. A plurality of control devices 320 may be arranged on the second surface of the stacked substrate 310, and respectively control the plurality of semiconductor devices 200. Each of the plurality of control devices 320 is electrically connected to the control electrode plate 240 and the sub-electrode plate 250 of each of the plurality of semiconductor devices 200 via a wiring within the stacked substrate 310. Each control device 320 controls the semiconductor device 200 by controlling a voltage of the control electrode plate 240 relative to the sub-electrode plate 250 of the semiconductor device 200. Each control device 320 may control one semiconductor device 200 by being connected to the one semiconductor device 200 or may control two or more semiconductor devices 200 by being connected to the two or more semiconductor devices 200. It is to be noted that the one or more control devices 320 may control the one or more semiconductor devices 200 by receiving a control signal from an external control apparatus. The at least one control device 320 may control at least one semiconductor device 200 according to a temperature of the at least one semiconductor device 200 detected by the temperature sensor 315. The control device 320 may acquire a lifetime of at least one semiconductor device 200 which is estimated from the temperature detected by the temperature sensor 315, and control the at least one semiconductor device 200 according to the lifetime of the at least one semiconductor device 200.

The at least one snubber capacitor 325 is arranged on the second surface of the stacked substrate 310 between the positive terminal connected to the high-potential wiring and the negative terminal connected to the low-potential wiring. Each of at least one snubber capacitor 325a and each of at least one snubber capacitor 325b may be connected in series and provided for each phase. In the present embodiment, a plurality of snubber capacitors 325a and a plurality of snubber capacitors 325b are provided. The plurality of snubber capacitors 325a and the plurality of snubber capacitors 325b are connected in series and are connected in parallel to the P wiring 350 and the N wiring 352. Thus, generation of transient high voltage when a corresponding semiconductor device 200 is switched is suppressed, and risk of a short circuit between the high potential and the low potential is eliminated even if one capacitor experiences a short circuit failure. It is to be noted that the plurality of snubber capacitors 325a and the plurality of snubber capacitors 325b may be mounted on the second surface of the stacked substrate 310 or may be provided in the inner layer of the stacked substrate 310.

The heat radiator 330 is fixed so as to come in contact with a surface of the plurality of semiconductor devices 200 on a side opposite to the stacked substrate 310. The heat radiator 330 may be, for example, a heat spreader, a heat sink, a liquid-cooling heat exchanger, a heat pipe, or a vapor chamber.

FIG. 5 illustrates a connection of each wiring within the semiconductor module 300 according to the present embodiment. In the present figure, the semiconductor device 200 (UU1) and the semiconductor device 200 (UU2) are allocated to a U-phase upper arm, and the semiconductor device 200 (UD1) and the semiconductor device 200 (UD2) are allocated to a U-phase lower arm. The second main electrode plate 230 of each semiconductor device 200 for the U-phase upper arm is connected to the P terminal via the P wiring 350. The first main electrode plate 220 of each semiconductor device 200 for the U-phase upper arm is connected to the U terminal via the U wiring 354. The second main electrode plate 230 of each semiconductor device 200 for the U-phase lower arm is connected to the U terminal and the first main electrode plate 220 of each semiconductor device 200 for the U-phase upper arm via the U wiring 354. The first main electrode plate 220 of each semiconductor device 200 for the U-phase lower arm is connected to the N terminal via the N wiring 352. By these connections, each semiconductor device 200 for the U-phase upper arm and each semiconductor device 200 for the U-phase lower arm are connected in series in this order between the P terminal and the N terminal, and a node between the first main electrode plate 220, which is for example a source, of each semiconductor device 200 for the U-phase upper arm and the second main electrode plate 230, which is for example a drain, of each semiconductor device 200 for the U-phase lower arm are connected to the U terminal.

The semiconductor device 200 (VU1) and the semiconductor device 200 (VU2) are allocated to a V-phase upper arm, and the semiconductor device 200 (VD1) and the semiconductor device 200 (VD2) are allocated to a V-phase lower arm. Each semiconductor device 200 for the V-phase upper arm and the V-phase lower arm is connected similarly to each semiconductor device 200 for the U-phase upper arm and the U-phase lower arm except that it is connected to the V terminal instead of the U terminal.

The semiconductor device 200 (WU1) and the semiconductor device 200 (WU2) are allocated to a W-phase upper arm, and the semiconductor device 200 (WD1) and the semiconductor device 200 (WD2) are allocated to a W-phase lower arm. Each semiconductor device 200 for the W-phase upper arm and the W-phase lower arm is connected similarly to each semiconductor device 200 for the U-phase upper arm and the U-phase lower arm except that is connected to the W terminal instead of the U terminal.

As illustrated in the present figure, each semiconductor device 200 allocated to the upper arm of each phase among the plurality of semiconductor devices 200 may be arranged in one row, which is a row on an upper side in the figure, on the first surface of the stacked substrate 310. Each semiconductor device 200 allocated to the lower arm of each phase among the plurality of semiconductor devices 200 may be arranged in one row, which is a row on a lower side in the figure, beside the row of each semiconductor device 200 allocated to the upper arm of each phase on the first surface of the stacked substrate 310. With such an arrangement, the second main electrode plate 230 of each semiconductor device 200 for the upper arms and the first main electrode plate 220 of each semiconductor device 200 for the lower arms are each arranged in one row, so that the P wiring 350 and the N wiring 352 can each extend in an array direction of each semiconductor device 200 for the upper arms and in an array direction of each semiconductor device 200 for the lower arms so as to be connected to each semiconductor device 200. Accordingly, the U wiring 354, the V wiring 356, and the W wiring 358 also can extend in the array direction of each semiconductor device 200 so as to be connected to the corresponding first main electrode plate 220 of each semiconductor device 200 for the upper arms and the corresponding second main electrode plate 230 of each semiconductor device 200 for the lower arms.

As illustrated in the present figure, on the first surface of the stacked substrate 310, each semiconductor device 200 allocated to the upper arm of each phase may be arranged in an orientation in which the first main electrode plate 220 is positioned on a side with the semiconductor device 200 allocated to the opposing lower arm among the plurality of semiconductor devices 200, which, in the figure, is an orientation in which the first main electrode plate 220 is on the lower side in the figure. On the first surface of the stacked substrate 310, each semiconductor device 200 allocated to the lower arm of each phase may be arranged in an orientation in which the first main electrode plate 220 is positioned on a side with the semiconductor device 200 allocated to the opposing upper arm among the plurality of semiconductor devices 200, which, in the figure, is an orientation in which the first main electrode plate 220 is on the upper side in the figure. In such an arrangement, the control electrode plate 240 and the sub-electrode plate 250 of each semiconductor device 200 are positioned at an end, on a side opposite to the semiconductor device 200 for the opposing arm, of the semiconductor device 200. Thus, the semiconductor devices 200 for the upper and lower arms oppose each other, and control wiring can be arranged on an outside of a region in which the P wiring 350, the N wiring 352, the U wiring 354, the V wiring 356, and the W wiring 358, through which a large current flows, are arranged.

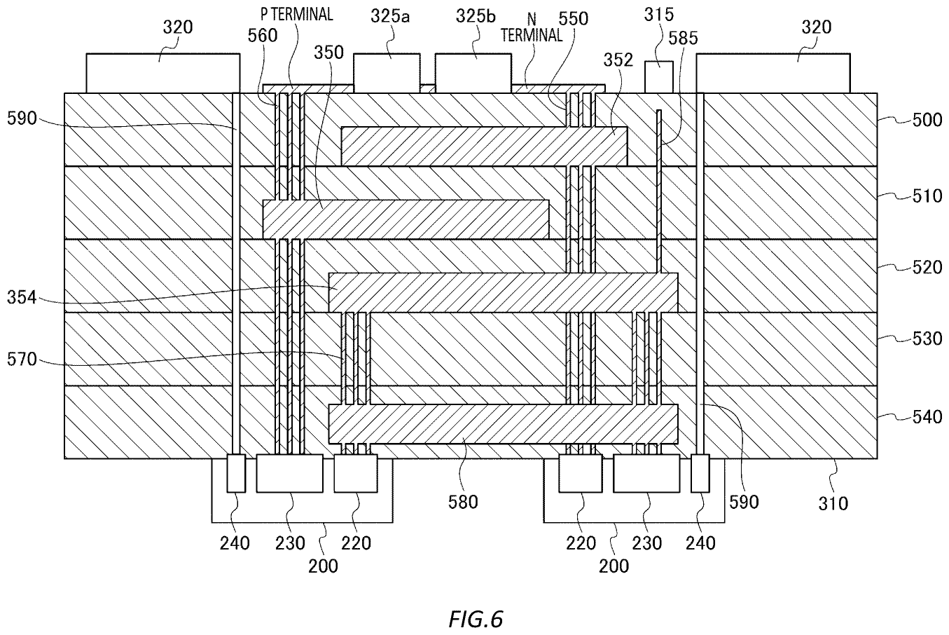

FIG. 6 is a schematic cross-sectional view illustrating the semiconductor module 300 according to the present embodiment. FIG. 6 illustrates the schematic cross-section of the semiconductor module 300 taken along a direction in which the semiconductor devices 200 for the upper and lower arms oppose each other and in the stack direction of the stacked substrate 310. The stacked substrate 310 has, in the stack direction from the side with the second surface toward a side with the first surface, a first level wiring layer 500, a second level wiring layer 510, a third level wiring layer 520, a fourth level wiring layer 530, a fifth level wiring layer 540, and a plurality of conductors. Herein, each of the plurality of conductors in the stacked substrate 310 may be a via, a copper inlay, a copper pin, or the like used to connect components in the stack direction.

One surface of the first level wiring layer 500 which is exposed makes up the second surface of the stacked substrate 310, and another surface comes in direct contact with the second level wiring layer 510. The first level wiring layer 500 has the N wiring 352. The N wiring 352 is connected to the first main electrode plate 220 of each semiconductor device 200 for the lower arms and the N terminal via an N potential conductor 550. Thus, the first main electrode plate 220 of each semiconductor device 200 and the N terminal are electrically connected by the N potential conductor 550 and the N wiring 352. A plurality of N potential conductors 550 may be arranged, and the N potential conductor 550 may be a conductor which penetrates the stacked substrate 310, which is a penetrating conductor, or a conductor which does not penetrate the stacked substrate 310, which is a non-penetrating conductor. The first level wiring layer 500 is an example of a second wiring layer in the present application.

One surface of the second level wiring layer 510 comes in direct contact with the third level wiring layer 520. The second level wiring layer 510 has the P wiring 350. The P wiring 350 is connected to the second main electrode plate 230 of each semiconductor device 200 for the upper arms and the P terminal via a P potential conductor 560. Thus, the second main electrode plate 230 of each semiconductor device 200 and the P terminal are electrically connected by the P potential conductor 560 and the P wiring 350. A plurality of P potential conductors 560 may be arranged, and the P potential conductor 560 may be a conductor which penetrates the stacked substrate 310, which is a penetrating conductor, or a conductor which does not penetrate the stacked substrate 310, which is a non-penetrating conductor. The second level wiring layer 510 is an example of a first wiring layer in the present application.

In the adjacent first level wiring layer 500 and second level wiring layer 510, the high-potential wiring, which is the P wiring 350, and the low-potential wiring, which is the N wiring 352, are at least partially overlapped with each other in the stack direction. The P wiring 350 may extend from the P potential conductor 560 connected thereto toward the N potential conductor 550, and the N wiring 352 may extend from the N potential conductor 550 toward the P potential conductor 560. Thus, the P wiring 350 and the N wiring 352 overlap with each other in the stack direction between the P potential conductor 560 and the N potential conductor 550. According to the present embodiment, by arranging the high-potential wiring and the low-potential wiring to which a DC voltage is applied such that they overlap in the stack direction of the wiring layers, magnetic fluxes caused by flowing currents cancel each other out, and wiring inductance can be reduced. Even when a current flowing through the semiconductor module 300 increases in accordance with increased capacity of a power converter, a voltage overshoot due to wiring inductance can be reduced.

One surface of the third level wiring layer 520 comes in direct contact with the fourth level wiring layer 530. The third level wiring layer 520 has the U wiring 354. The U wiring 354 is connected to the first main electrode plate 220 of each semiconductor device 200 for the U-phase upper arm, the second main electrode plate 230 of each semiconductor device 200 for the U-phase lower arm, and the U terminal via a U-phase potential conductor 570. Thus, the first main electrode plate 220 of each semiconductor device 200 for the U-phase upper arm, the second main electrode plate 230 of each semiconductor device 200 for the U-phase lower arm, and the U terminal are electrically connected by the U-phase potential conductor 570 and the U wiring 354. A plurality of U-phase potential conductors 570 may be arranged, and the U-phase potential conductor 570 may be formed in a non-penetrating way in the stacked substrate 310.

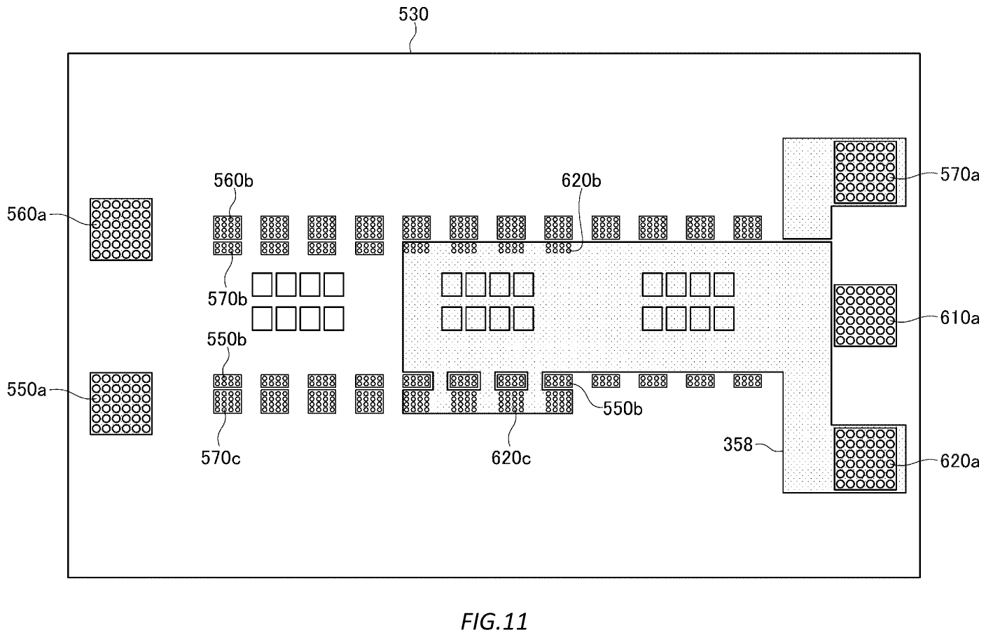

One surface of the fourth level wiring layer 530 comes in direct contact with the fifth level wiring layer 540. The fourth level wiring layer 530 may have the W wiring 358 which is not illustrated, and is described in detail with reference to FIG. 11.

One surface of the fifth level wiring layer 540 which is exposed makes up the first surface of the stacked substrate 310. The fifth level wiring layer 540 has a U connection wiring 580. The U connection wiring 580 connects the plurality of semiconductor devices 200 mounted on the first surface of the stacked substrate 310 to each other via the U-phase potential conductor 570. One end of the U-phase potential conductor 570 may be connected to a main electrode plate of at least one semiconductor device 200 among the plurality of semiconductor devices 200, and extend to the fifth level wiring layer 540. The U connection wiring 580 may connect the first main electrode plate 220 of a first semiconductor device 200 among the plurality of semiconductor devices 200 and the second main electrode plate 230 of a second semiconductor device 200 among the plurality of semiconductor devices 200 to each other via the U-phase potential conductor 570. In the present embodiment, the U connection wiring 580 connects each semiconductor device 200 for the U-phase upper arm and each semiconductor device 200 for the U-phase lower arm to each other in series. The U connection wiring 580 connects the first main electrode plate 220 of each semiconductor device 200 for the U-phase upper arm and the second main electrode plate 230 of each semiconductor device 200 for the U-phase lower arm to each other via the U-phase potential conductor 570. The fifth level wiring layer 540 is an example of a third wiring layer of the present application.

The high-potential wiring, which is the P wiring 350, and the low-potential wiring, which is the N wiring 352, may be at least partially overlapped with an output wiring in the stack direction. The P wiring 350 and the N wiring 352 may be overlapped with at least one of the U wiring 354, the V wiring 356, and the W wiring 358 in the stack direction. According to the present embodiment, by arranging the high-potential wiring and the low-potential wiring to which a DC voltage is applied such that they overlap with the output wiring in the stack direction, magnetic fluxes caused by flowing currents cancel each other out, and wiring inductance can be further reduced.

The stacked substrate 310 may have a temperature detection conductor 585 which is non-penetrating. The temperature detection conductor 585 may be a via, a copper inlay, a copper pin, or the like which extends in the stack direction in the stacked substrate 310. The temperature detection conductor 585 may be formed between at least one temperature sensor 315 and at least one of the plurality of semiconductor devices 200 in the stack direction. The temperature detection conductor 585 may include a conductor such as a metal inside. The temperature detection conductor 585 may be formed between the temperature sensor 315 and the semiconductor device 200 to be detected by the temperature sensor 315 in the stack direction in the stacked substrate 310. The temperature detection conductor 585 may extend from a wiring layer, among the plurality of wiring layers, which is connected to at least one of the plurality of semiconductor devices 200 toward the second surface of the stacked substrate 310 in the stack direction. The temperature detection conductor 585 may be formed extending from the wiring layer to directly below the semiconductor device 200 to be detected. One or more temperature detection conductors 585 may be formed for each semiconductor device 200 to be detected. In the present embodiment, the temperature detection conductor 585 may extend from the U wiring 354 of the third level wiring layer 520 to within the first level wiring layer 500, and be formed in a non-penetrating way. Since the temperature detection conductor 585 is non-penetrating, it is not exposed to an outside of the stacked substrate 310. The temperature detection conductor 585 may be formed in the stacked substrate 310 so as to not connected to a wiring, such as the P wiring 350 and the N wiring 352, other than the connected wiring, which is the U wiring 354. It is to be noted that the temperature detection conductor 585 may not be connected to any wiring within the stacked substrate 310. The temperature detection conductor 585 may be filled with a metal or the like inside. According to the temperature detection conductor 585, a temperature of the semiconductor device 200 on the side with the first surface can be efficiently transmitted to the temperature sensor 315 on the side with the second surface.

The control devices 320 is electrically connected to the control electrode plate 240 and the sub-electrode plate 250 of the semiconductor device 200 via a control conductor 590 within the stacked substrate 310. Next, each wiring layer of the stacked substrate 310 according to the present embodiment will be described.

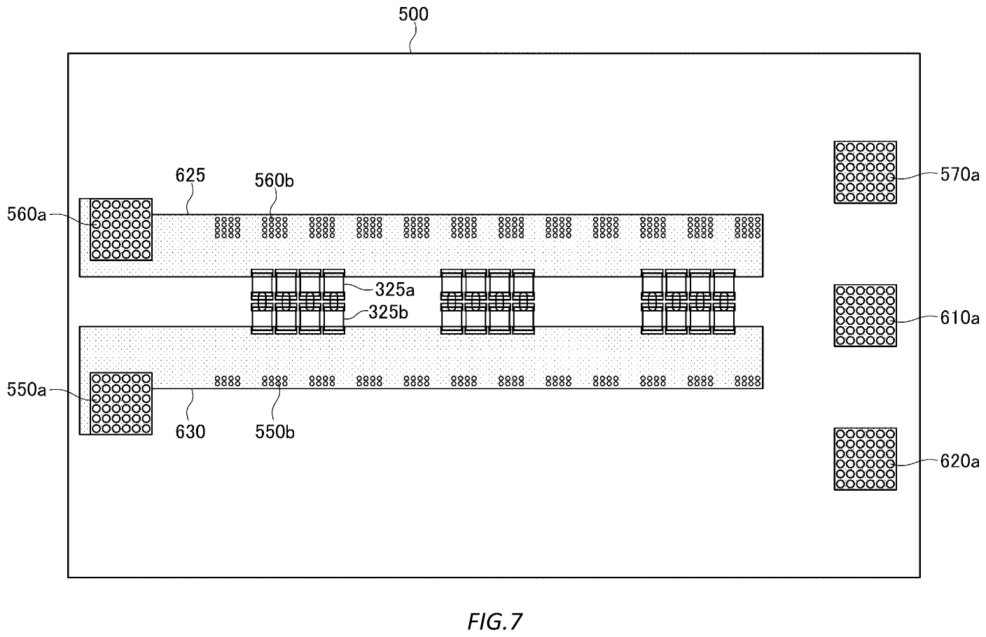

FIG. 7 is a schematic top view illustrating the second surface of the stacked substrate 310 of the semiconductor module 300 illustrated in FIG. 6. The control device 320, the temperature sensor 315, and the like of the semiconductor module 300 are omitted in FIG. 7. It is to be noted that FIG. 7 to FIG. 12 illustrate a configuration for arranging twelve semiconductor devices 200 for the upper arm, which is four semiconductor devices 200 for each phase of the upper arm, and twelve semiconductor devices 200 for the lower arm, which is four semiconductor devices 200 for each phase of the lower arm, the stacked substrate 310 is not limited to this and, for example, can be configured similarly to the semiconductor module 300 illustrated in FIG. 3 to FIG. 5 for arranging six semiconductor devices 200 for the upper arm and six semiconductor devices 200 for the lower arm. The plurality of semiconductor devices 200 can be mounted on the stacked substrate 310 of the present embodiment from a side with the P terminal or the N terminal to a side with the output terminal, in an order of the U-phase, the W-phase, and the V-phase.

The stacked substrate 310 has, on the second surface, a P potential conductor 560a connected to the P terminal a P potential conductor 560b connected to the semiconductor device 200, a N potential conductor 550a connected to the N terminal, a N potential conductor 550b connected to the semiconductor device 200, a U-phase potential conductor 570a connected to the U terminal, a V-phase potential conductor 610a connected to the V terminal, and a W-phase potential conductor 620a connected to the W terminal. On the second surface of the stacked substrate 310, the P terminal is formed on the P potential conductor 560a, the N terminal is formed on the N potential conductor 550a, the U terminal is formed on the U-phase potential conductor 570a, the V terminal is formed on the V-phase potential conductor 610a, and the W terminal is formed on the W-phase potential conductor 620a. It is to be noted that each conductor is illustrated as a circle in the present figure, and the figures below are similar.

One or more P potential conductors 560b may be formed at positions corresponding to each semiconductor device 200 for the upper arm. The plurality of P potential conductors 560b are arranged side by side on the second surface from the P terminal toward the U terminal, the V terminal, and the W terminal. One or more N potential conductors 550b may be formed at positions corresponding to each semiconductor device 200 for the lower arm. The plurality of N potential conductors 550b are arranged side by side on the second surface from the N terminal toward the U terminal, the V terminal, and the W terminal. A row of N potential conductors 550b and a row of P potential conductors 560b may be parallel to each other.

The stacked substrate 310 has a first surface wiring 625 and a second surface wiring 630 on the second surface. The first surface wiring 625 may electrically connects the plurality of P potential conductors 560 to each other, and further connect the plurality of P potential conductors 560 to the snubber capacitor 325a. The first surface wiring 625 is formed extending from the P terminal, which is on the P potential conductor 560a, to the plurality of P potential conductors 560b and the snubber capacitor 325a. The second surface wiring 630 may electrically connect the plurality of N potential conductors 550 to each other, and further connect the plurality of N potential conductors 550 to the snubber capacitor 325b. The second surface wiring 630 is formed extending from the N terminal, which is on the N potential conductor 550a, to the plurality of N potential conductors 550b and the snubber capacitor 325b.

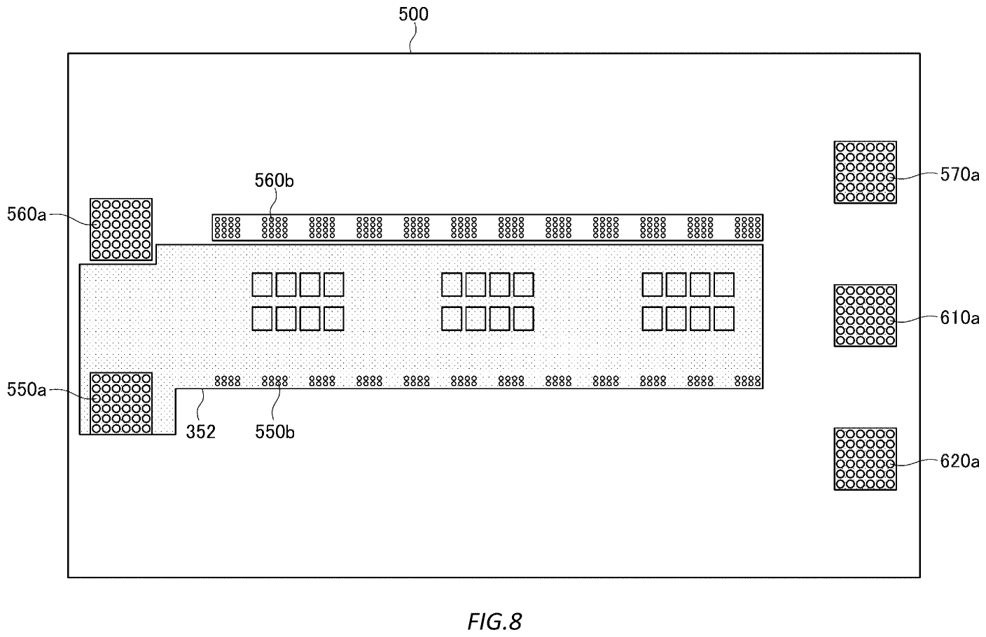

FIG. 8 is a schematic view of the first level wiring layer 500 of the stacked substrate 310 of the semiconductor module 300 illustrated in FIG. 6. FIG. 8 illustrates a surface of the first level wiring layer 500 which is perpendicular to the stack direction of the wiring layers inside the stacked substrate 310. A configuration relating to the control device 320 and the temperature sensor 315 of the semiconductor module 300 are omitted in FIG. 8. The first level wiring layer 500 has the N wiring 352.

The N wiring 352 in the first level wiring layer 500 electrically connects the plurality of N potential conductors 550 to each other, and connects the N terminal and each semiconductor device 200 for the lower arm. The N wiring 352 is connected to the N terminal via the N potential conductor 550a, and is connected to each semiconductor device 200 for the lower arm via the N potential conductor 550b. The N wiring 352 is formed extending from the N potential conductor 550a to the plurality of N potential conductors 550b. The N wiring 352 is further formed extending from the row of N potential conductors 550b to a direction of the row of P potential conductor 560b, and is formed in a region between the row of the plurality of N potential conductors 550b and the row of the plurality of P potential conductors 560b so as to not come in contact with the P potential conductors 560. The N wiring 352 may be formed extending from the N potential conductors 550b to a position exceeding a midpoint between the row of N potential conductors 550b and the row of P potential conductors 560b. All of the P potential conductors 560 in the first level wiring layer 500 may be connected to each other by a wiring which is separated from the N wiring 352.

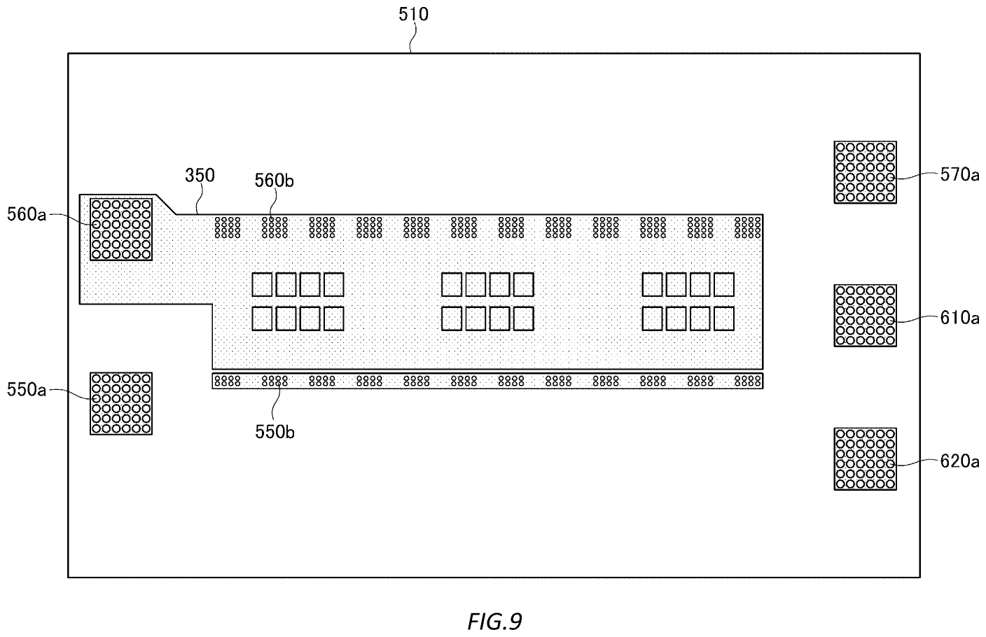

FIG. 9 is a schematic view of the second level wiring layer 510 of the stacked substrate 310 of the semiconductor module 300 illustrated in FIG. 6. FIG. 9 illustrates a surface of the second level wiring layer 510 which is perpendicular to the stack direction of the wiring layers inside the stacked substrate 310. The configuration relating to the control device 320 and the temperature sensor 315 of the semiconductor module 300 are omitted in FIG. 9. The second level wiring layer 510 has the P wiring 350.

The P wiring 350 in the second level wiring layer 510 electrically connects the plurality of P potential conductors 560 to each other, and connects the P terminal and each semiconductor device 200 for the upper arm. The P wiring 350 is connected to the P terminal via the P potential conductor 560a, and is connected to each semiconductor device 200 for the upper arm via the P potential conductor 560b. The P wiring 350 is formed extending from the P potential conductor 560a to the plurality of P potential conductors 560b. The P wiring 350 is further formed extending from the row of P potential conductors 560b to a direction of the row of N potential conductor 550b, and is formed in a region between the row of the plurality of N potential conductors 550b and the row of the plurality of P potential conductors 560b so as to not come in contact with the N potential conductors 550. The P wiring 350 may be formed extending from the P potential conductors 560b to a position exceeding a midpoint between the row of P potential conductors 560b and the row of N potential conductors 550b. The P wiring 350 is formed up to a position close to the N potential conductors 550b so as to overlap with the N wiring 352 in the stack direction in the region between the row of N potential conductors 550b and the row of P potential conductors 560b. The N potential conductors 550b may be connected to each other by a wiring which is separated from the P wiring 350.

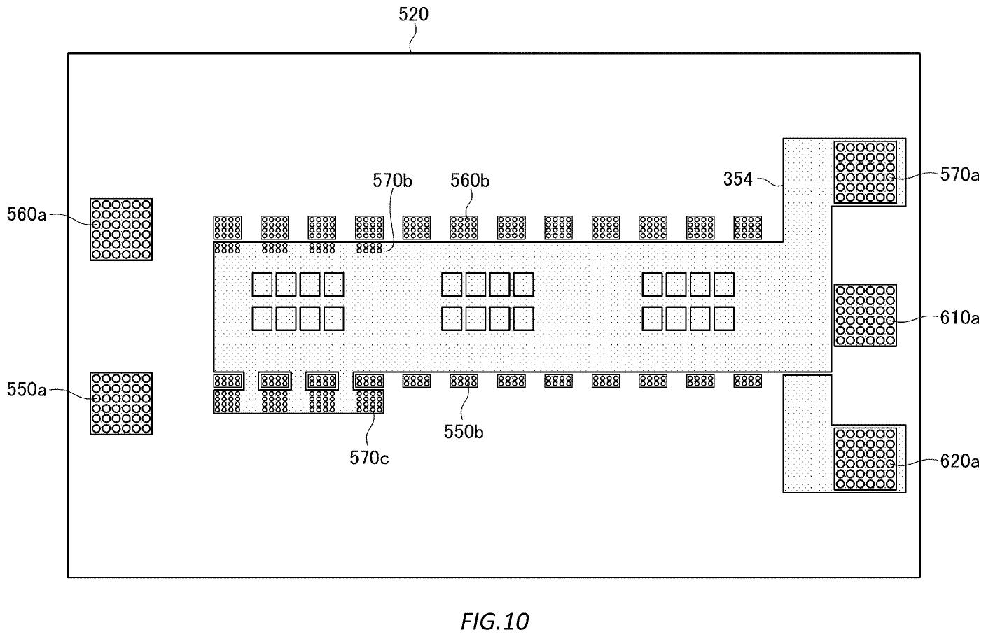

FIG. 10 is a schematic view of the third level wiring layer 520 of the stacked substrate 310 of the semiconductor module 300 illustrated in FIG. 6. FIG. 10 illustrates a surface of the third level wiring layer 520 which is perpendicular to the stack direction of the wiring layers inside the stacked substrate 310. The configuration relating to the control device 320 and the temperature sensor 315 of the semiconductor module 300 are omitted in FIG. 10. The third level wiring layer 520 has the U wiring 354, and is an example of a fourth wiring layer of the present application.

The U wiring 354 in the third level wiring layer 520 electrically connects the plurality of U-phase potential conductors 570 to each other, and connects the U terminal and each semiconductor device 200 for the U-phase. The U wiring 354 is connected to the U terminal via the U-phase potential conductor 570a, is connected to the semiconductor devices 200 for the U-phase upper arm via U-phase potential conductors 570b, and is connected to the semiconductor devices 200 for the U-phase lower arm via U-phase potential conductors 570c. In the third level wiring layer 520, the U wiring 354 is separated, i.e. insulated, from the P potential conductor 560, the N potential conductor 550, and the like. The U wiring 354 overlaps with the N wiring 352 and the P wiring 350 in the stack direction in the region between the row of N potential conductors 550b and the row of P potential conductors 560b.

FIG. 11 is a schematic view of the fourth level wiring layer 530 of the stacked substrate 310 of the semiconductor module 300 illustrated in FIG. 6. FIG. 11 illustrates a surface of the fourth level wiring layer 530 which is perpendicular to the stack direction of the wiring layers inside the stacked substrate 310. The configuration relating to the control device 320 and the temperature sensor 315 of the semiconductor module 300 are omitted in FIG. 11. The fourth level wiring layer 530 has the W wiring 358, and is an example of the fourth wiring layer of the present application.

The W wiring 358 in the fourth level wiring layer 530 electrically connects a plurality of W-phase potential conductors 620 to each other, and connects the W terminal and each semiconductor device 200 for the W-phase. The W wiring 358 is connected to the W terminal via the W-phase potential conductor 620a, is connected to the semiconductor devices 200 for the W-phase upper arm via W-phase potential conductors 620b, and is connected to the semiconductor devices 200 for the W-phase lower arm via W-phase potential conductors 620c. The W wiring 358 overlaps with the N wiring 352 and the P wiring 350 in the stack direction in the region between the row of N potential conductors 550b and the row of P potential conductors 560b.

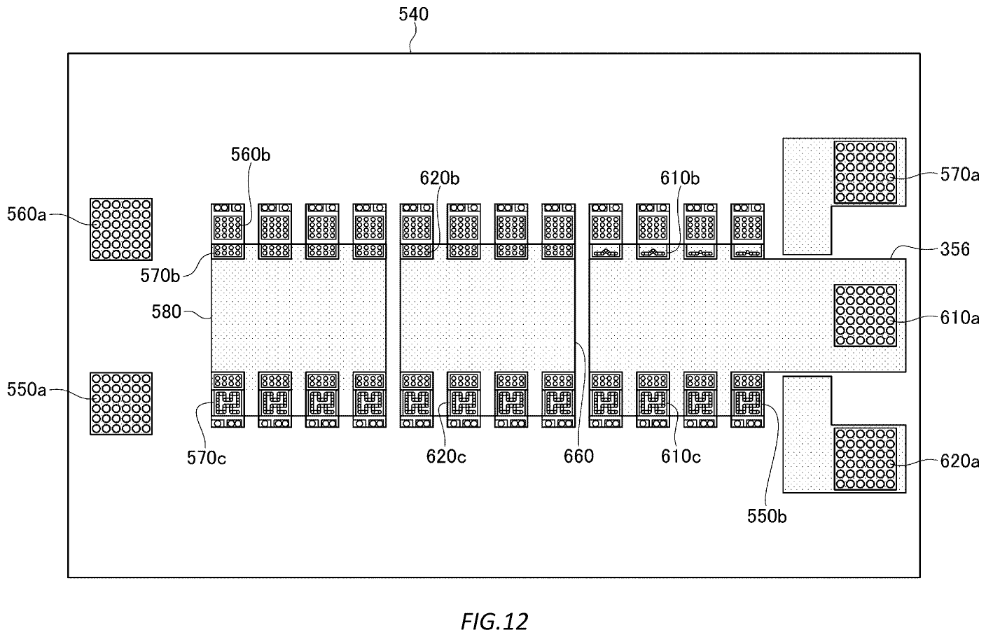

FIG. 12 is a schematic view of the fifth level wiring layer 540 of the stacked substrate 310 of the semiconductor module 300 illustrated in FIG. 6. FIG. 12 illustrates a surface of the fifth level wiring layer 540 which is perpendicular to the stack direction of the wiring layers inside the stacked substrate 310. The configuration relating to the control device 320 and the temperature sensor 315 of the semiconductor module 300 are omitted in FIG. 12. The fifth level wiring layer 540 has the V wiring 356, the U connection wiring 580, and a W connection wiring 660. The fifth level wiring layer 540 has the output wiring and the connection wiring, and is an example of the third wiring layer or the fourth wiring layer of the present application.

The V wiring 356 in the fifth level wiring layer 540 electrically connects a plurality of V-phase potential conductors 610 to each other, and connects the V terminal and each semiconductor device 200 for the V-phase. The V wiring 356 is connected to the V terminal via the V-phase potential conductor 610a, is connected to the semiconductor devices 200 for the V-phase upper arm via V-phase potential conductors 610b, and is connected to the semiconductor devices 200 for the V-phase lower arm via V-phase potential conductors 610c. The V wiring 356 overlaps with the N wiring 352 and the P wiring 350 in the stack direction in the region between the row of N potential conductors 550b and the row of P potential conductors 560b.

The U connection wiring 580 in the fifth level wiring layer 540 electrically connects the plurality of U-phase potential conductors 570b and 570c to each other, and connects the semiconductor devices 200 for the U-phase upper arm and the semiconductor devices 200 for the U-phase lower arm to each other in series. The U connection wiring 580 may be connected to the first main electrode plate 220 of each semiconductor device 200 for the U-phase upper arm via the U-phase potential conductor 570b, and connected to the second main electrode plate 230 of each semiconductor device 200 for the U-phase lower arm via the U-phase potential conductor 570c. The U connection wiring 580 may be at least partially overlapped with the P wiring 350 and the N wiring 352 in the stack direction. The U connection wiring 580 may overlap with the N wiring 352 and the P wiring 350 in the stack direction in the region between the row of N potential conductors 550b and the row of P potential conductors 560b.

The W connection wiring 660 in the fourth level wiring layer 530 electrically connects the plurality of W-phase potential conductors 620b and 620c to each other, and connects the semiconductor devices 200 for the W-phase upper arm and the semiconductor devices 200 for the W-phase lower arm to each other in series. The W connection wiring 660 may be connected to the first main electrode plate 220 of each semiconductor device 200 for the W-phase upper arm via the W-phase potential conductor 620b, and connected to the second main electrode plate 230 of each semiconductor device 200 for the W-phase lower arm via the W-phase potential conductor 620c. The W connection wiring 660 is arranged between the U connection wiring 580 and the V wiring 356. The W connection wiring 660 may be at least partially overlapped with the P wiring 350 and the N wiring 352 in the stack direction. The W connection wiring 660 may overlap with the N wiring 352 and the P wiring 350 in the stack direction in the region between the row of N potential conductors 550b and the row of P potential conductors 560b.

According to the present embodiment, the N wiring 352 and the P wiring 350 are overlapped with each other and further overlapped with the output wiring in the stack direction, such that magnetic fluxes caused by currents flowing through the wiring cancel each other out, and wiring inductance can be reduced. By providing one wiring of high potential in each wiring layer in the stacked substrate 310, insulation performance can be ensured. By using, for example, a half-buried via, such as an IVH or an Inner Via Hole or a BVH or a Buried Via Hole, as a connection to the output terminal or the like, packaging density can be improved and the temperature sensor 315 can be arranged directly above the semiconductor device 200.

It is to be noted that in the stacked substrate 310 of the present embodiment, the N wiring 352 and the P wiring 350 may not be formed in adjacent wiring layers, and for example, a wiring layer having at least one of the U wiring 354, the V wiring 356, and the W wiring 358 may be arranged between a wiring layer in which the N wiring 352 is arranged and a wiring layer in which the P wiring 350 is arranged.

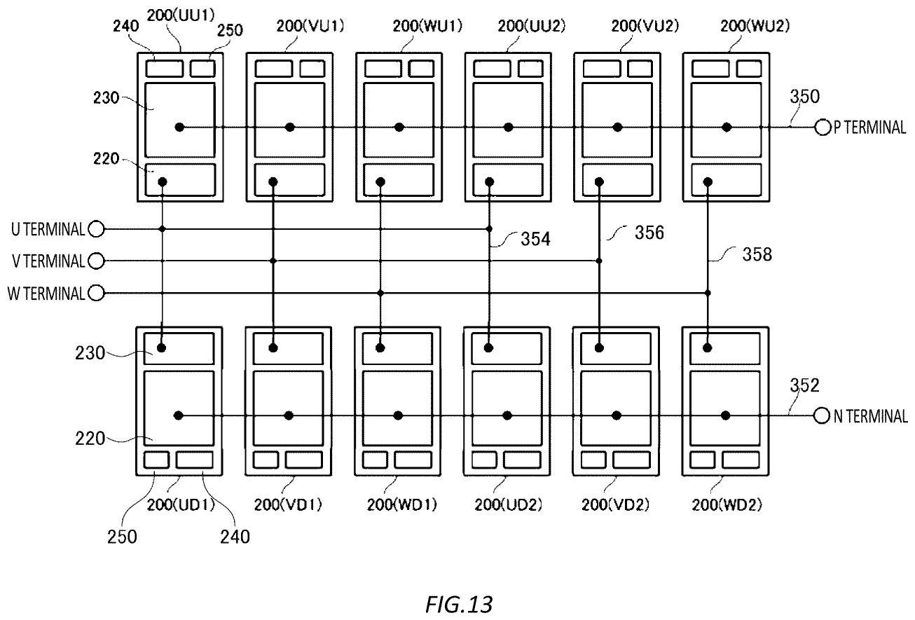

FIG. 13 illustrates another example of the connection of each wiring within the semiconductor module 300 according to the present embodiment. The wiring illustrated in FIG. 13 may be similar to the wiring illustrated in FIG. 5, but an arrangement of the electrode plates of the semiconductor device 200 is different. In the present figure, the semiconductor devices 200 for the upper arm may be mounted, on the first surface of the stacked substrate 310, such that the first main electrode plate 220 is closer to the semiconductor devices 200 for the lower arm than the second main electrode plate 230, and the semiconductor devices 200 for the lower arm may be mounted, on the first surface of the stacked substrate 310, such that the second main electrode plate 230 is closer to the semiconductor devices 200 for the upper arm than the first main electrode plate 220. In the present figure, the second main electrode plate 230 of each semiconductor device 200 for the upper arm is connected to the P terminal via the P wiring 350. The first main electrode plate 220 of the semiconductor devices 200 for the upper arm is each connected to the U terminal, the V terminal, and the W terminal via the U wiring 354, the V wiring 356, and the W wiring 358. The second main electrode plate 230 of each semiconductor device 200 for the upper arm is arranged between the control electrode plate 240 and the first main electrode plate 220. The first main electrode plate 220 of each semiconductor device 200 for the lower arm is connected to the N terminal via the N wiring 352. The second main electrode plate 230 of the semiconductor devices 200 for the lower arm is each connected to the U terminal, the V terminal, and the W terminal via the U wiring 354, the V wiring 356, and the W wiring 358. The first main electrode plate 220 of each semiconductor device 200 for the lower arm is arranged between the control electrode plate 240 and the second main electrode plate 230.

According to such a wiring, a connection wiring which connects the semiconductor devices 200 for the upper arm and the semiconductor devices 200 for the lower arm in series can be easily formed having a smaller width.

It is to be noted that in the above-described embodiment, an example in which the semiconductor module 300 is a three-phase inverter having three output terminals has been illustrated, but the semiconductor module 300 of the present embodiment is not limited to this and may have only one output terminal for the P terminal and the N terminal.

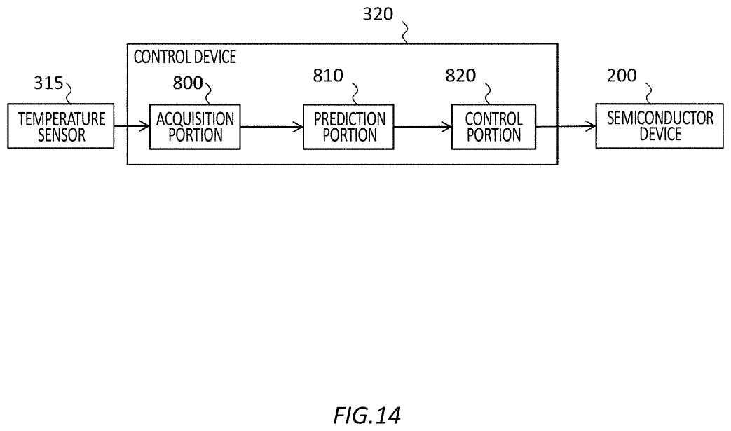

FIG. 14 illustrates a configuration example of the control device 320 of the semiconductor module 300. FIG. 14 illustrates the control device 320 together with the semiconductor device 200 to be controlled and the temperature sensor 315 which detects a temperature of the semiconductor device 200 to be controlled. The control device 320 in the present figure may be an example of one of the plurality of control devices 320 of the semiconductor module 300 illustrated in FIG. 3 or FIG. 6.

The control device 320 has an acquisition portion 800, a prediction portion 810, and a control portion 820. The acquisition portion 800 is connected to the temperature sensor 315 and the prediction portion 810. The acquisition portion 800 acquires a detected temperature of the semiconductor device 200 detected by the temperature sensor 315. The acquisition portion 800 may receive information of a current or the like representing the detected temperature from the temperature sensor 315, and calculate the detected temperature from the received information.

The prediction portion 810 is connected to the control portion 820. The prediction portion 810 may predict a lifetime of the corresponding semiconductor device 200 from the detected temperature acquired by the acquisition portion 800. The prediction portion 810 may predict the lifetime, as an example, a remaining usage period of the semiconductor device 200 or whether or not the lifetime is short, according to a change in the detected temperature. The prediction portion 810 may predict the lifetime by using a rainflow method. The prediction portion 810 may calculate an amount of change in the detected temperature for each predetermined period, as an example, for each acquisition cycle of the detected temperature by the acquisition portion 800, and predict that the lifetime is shorter than a predetermined lifetime threshold when a total of absolute values of the amount of change exceeds a predetermined threshold. The prediction portion 810 may predict the lifetime of the remaining usage period or the like of the semiconductor device 200 by using the total of absolute values of the amount of change in the detected temperature according to a pre-stored function indicating a relationship between the total of the absolute values of the amount of change in the detected temperature and the lifetime. The predetermined threshold or the function used by the prediction portion 810 may be previously acquired by an experiment or a simulation using a semiconductor device having a same structure as the semiconductor device 200.

The control portion 820 is connected to the semiconductor device 200 to be controlled. The control portion 820 controls the semiconductor device 200. In controlling the semiconductor device 200, the control portion 820 may change a gate output voltage or a gate resistance for the semiconductor device 200 according to the lifetime predicted by the prediction portion 810.

According to the present embodiment, by controlling each semiconductor device 200 according to the lifetime predicted from the detected temperature, lifetimes of the plurality of semiconductor devices 200 in the semiconductor module 300 can be made uniform, and heat concentration can be suppressed.

It is to be noted that an external control apparatus may execute an operation at least a part of the acquisition portion 800, the prediction portion 810, and the control portion 820. In this case, the external control apparatus may acquire the temperature detected by the temperature sensor 315, predict the lifetime of the semiconductor device 200 according to the detected temperature, and send a control signal corresponding to the lifetime to the control device 320. The control device 320 may control the semiconductor device 200 according to the control signal from the external control apparatus.

While the present invention has been described by way of the embodiments, the technical scope of the present invention is not limited to the scope described in the above-described embodiments. It is apparent to persons skilled in the art that various alterations or improvements can be made to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A semiconductor module, comprising:
a stacked substrate in which a plurality of wiring layers are stacked; and
a plurality of semiconductor devices mounted on a first surface of the stacked substrate, wherein
the plurality of wiring layers have
a first wiring layer having a high-potential wiring to which a high potential is applied,
a second wiring layer having a low-potential wiring to which a low potential is applied, and
a third wiring layer having a connection wiring which connects the plurality of semiconductor devices mounted on the first surface of the stacked substrate to each other, and
the high-potential wiring and the low-potential wiring are at least partially overlapped with each other in a stack direction.

2. The semiconductor module according to claim 1, comprising
at least one temperature sensor which is arranged on a side with a second surface of the stacked substrate and detects a temperature of at least one of the plurality of semiconductor devices.

3. The semiconductor module according to claim 2, comprising
a plurality of temperature sensors, each temperature sensor being identical to the temperature sensor, which are arranged on the side with the second surface of the stacked substrate and each detects a temperature of the plurality of semiconductor devices.

4. The semiconductor module according to claim 2, wherein
the at least one temperature sensor is arranged so as to be overlapped with the at least one of the plurality of semiconductor devices in the stack direction.

5. The semiconductor module according to claim 2, wherein
the stacked substrate includes a conductor of which one end is connected to a main electrode plate of at least one semiconductor device among the plurality of semiconductor devices, and which extends to the third wiring layer.

6. The semiconductor module according to claim 5, wherein
the conductor is formed in a non-penetrating way in the stacked substrate.

7. The semiconductor module according to claim 5, wherein
the temperature sensor corresponding to at least one semiconductor device among the plurality of semiconductor devices is mounted at a position which overlaps with the conductor connected to the semiconductor device in the stack direction.

8. The semiconductor module according to claim 2, wherein
the stacked substrate has a temperature detection conductor, which is non-penetrating, between the at least one temperature sensor and the at least one of the plurality of semiconductor devices in the stack direction.

9. The semiconductor module according to claim 8, wherein
the temperature detection conductor extends from a wiring layer, among the plurality of wiring layers, which is connected to the at least one of the plurality of semiconductor devices toward the second surface of the stacked substrate in the stack direction.

10. The semiconductor module according to claim 2, comprising
at least one control device which is arranged on the second surface of the stacked substrate, and controls the at least one semiconductor device, wherein
the control device controls the at least one semiconductor device according to the temperature of the at least one semiconductor device detected by the temperature sensor.

11. The semiconductor module according to claim 10, wherein
the control device acquires a lifetime of the at least one semiconductor device which is estimated from the temperature detected by the temperature sensor, and controls the at least one semiconductor device according to the lifetime of the at least one semiconductor device.

12. The semiconductor module according to claim 10, wherein
a plurality of control devices, each control device being identical to the control device, are arranged on the second surface of the stacked substrate, and respectively control the plurality of semiconductor devices.

13. The semiconductor module according to claim 1, wherein
each of the plurality of semiconductor devices is provided with a first main electrode plate, a second main electrode plate, and a control electrode plate on one surface thereof, and has a switching element in which a first main electrode is connected to the first main electrode plate, a second main electrode is connected to the second main electrode plate, and a control electrode is connected to the control electrode plate, and
the connection wiring of the third wiring layer connects the first main electrode plate of a first semiconductor device among the plurality of semiconductor devices, and the second main electrode plate of a second semiconductor device among the plurality of semiconductor devices to each other.

14. The semiconductor module according to claim 13, wherein
the first semiconductor device is mounted, on the first surface of the stacked substrate, such that the first main electrode plate is closer to the second semiconductor device than the second main electrode plate, and the second semiconductor device is mounted, on the first surface of the stacked substrate, such that the second main electrode plate is closer to the first semiconductor device than the first main electrode plate.

15. The semiconductor module according to claim 1, wherein
the high-potential wiring and the low-potential wiring are at least partially overlapped with the connection wiring in the stack direction.

16. The semiconductor module according to claim 1, wherein
the plurality of wiring layers further have a fourth wiring layer having an output wiring which connects the plurality of semiconductor devices to an output terminal formed on a second surface of the stacked substrate.

17. The semiconductor module according to claim 16, wherein
the high-potential wiring and the low-potential wiring are at least partially overlapped with the output wiring in the stack direction.

18. The semiconductor module according to claim 1, comprising
at least one snubber capacitor which is arranged on a second surface of the stacked substrate between a positive terminal connected to the high-potential wiring and a negative terminal connected to the low-potential wiring.
